(19) United States
(12) Patent Application Publication
(10) Pub. No.: US 2022/0398068 A1
(43) Pub. Date: Dec. 15, 2022

(54) MAGNETIC-TUNNEL-JUNCTION-BASED RANDOM NUMBER GENERATOR

(71) Applicant: INTERNATIONAL BUSINESS MACHINES CORPORATION, ARMONK, NY (US)

(72) Inventors: Dimitri Houssameddine, Sunnyvale, CA (US); Kangguo Cheng, Schenectady, NY (US); Julien Frougier, Albany, NY (US); Ruilong Xie, Niskayuna, NY (US)

(21) Appl. No.: 17/303,864

(22) Filed: Jun. 9, 2021

(51) Int. Cl. G06F 7/58; G11C 11/16

(52) U.S. Cl. CPC G06F 7/588; G11C 11/161; G11C 11/1673

(57) ABSTRACT

According to one embodiment, a method, computer system, and computer program product for generating true random numbers is provided. The present invention may include applying an electrical current to an entirely on-chip magnetic tunnel junction (MTJ) to cause the MTJ to oscillate between a high resistance state and a low resistance state; responsive to removing the electrical current and allowing the MTJ to randomly relax into the high resistance state or the low resistance state, reading the resistance state of the MTJ.

### BACKGROUND

The present invention relates, generally, to the field of computing, and more particularly to random number generation.

Random number generation is the field concerned with generating a sequence of numbers or symbols that cannot be reasonably predicted better than by random chance. The ability to generate random numbers has practical applications in areas where unpredictability is desired, such as cryptography, computer simulation, completely randomized design, gambling, statistical sampling, et cetera.

### SUMMARY

According to one embodiment, a method, computer system, and computer program product for generating true random numbers is provided. The present invention may include applying an electrical current to an entirely on-chip magnetic tunnel junction (MTJ) to cause the MTJ to oscillate between a high resistance state and a low resistance state; responsive to removing the electrical current and allowing the MTJ to randomly relax into the high resistance state or the low resistance state, reading the resistance state of the MTJ.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 is a diagram illustrating an exemplary random number generator device according to at least one embodiment of the present invention;

FIG. 2 is an operational flowchart illustrating a random number generation process according to at least one embodiment of the present invention;

FIG. 3 is a diagram of the structure of an exemplary magnetic-tunnel-junction-based oscillator according to at least one embodiment of the present invention;

FIG. 4 is a diagram of the structure of an exemplary magnetic-tunnel-junction-based oscillator according to at least one embodiment of the present invention;

FIG. 5 depicts an example of the oscillation sequence of the exemplary magnetic-tunnel-junction-based oscillator of FIG. 4 according to at least one embodiment of the present invention.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

Embodiments of the present invention relate to the field of computing, and more particularly to random number generation. The following described exemplary embodiments provide a system, method, and program product to, among other things, utilize magnetic tunnel junctions (MTJs) to generate true random numbers based on the MTJs relaxing with equal probability into one of two stable resistance states after being excited to oscillation by a programming pulse. Therefore, the present embodiment has the capacity to improve the technical field of random number generation by providing a purely on-chip system that generates truly random numbers from a high-entropy source with a minimal blocking period and which relies solely on electronic signals such that no additional circuits or power is required to process analogue signals (e.g., thermal fluctuations) into digital signals, and no off-chip components are required whose communications with the chip may be intercepted.

As previously described, random number generation is the field concerned with generating a sequence of numbers or symbols that cannot be reasonably predicted better than by random chance. The ability to generate random numbers has practical applications in areas where unpredictability is desired, such as cryptography, computer simulation, completely randomized design, gambling, statistical sampling, et cetera.

There are two main types of random number generator: hardware random-number generators (HRNGS), which generate truly random numbers as a function of the current value of some physical environment attribute that is constantly changing in a manner that is practically impossible to model, and may then compensate for possible biases in the measurement process; and pseudorandom number generators (PRNGS), which utilizes computational algorithms to generate numbers that look random, but are actually deterministic and can be reproduced if the state of the PRNG is known.

While PRNGs are not truly random due to the deterministic nature of software programming, often times they yield numbers of sufficient randomness for most purposes. However, for some applications such as security key generation for cryptography, statistical simulation such as Monte-Carlo simulations, and gambling systems, truly random numbers beyond the capabilities of PRNGs are required. In such cases, TRNGs must be employed. Conventional hardware TRNGs use entropy from natural sources such as thermal fluctuation and flicker noise, making them less vulnerable to attack. The drawbacks of such TRNGs is that they require analogue circuits to convert analog signals into digital signals, posing challenges in integrating them with low-power digital chips. As a result, hardware TRNGs are typically off-chip, meaning that they are fabricated separately with legacy technology nodes and mounted next to advanced digital chips such as microprocessors at packing levels. The problem with off-chip TRNGs is that communication between TRNG chips and microprocessors are vulnerable to bus snooping (e.g., side-channel attacks).

Magnetic tunnel junction (MTJ) based approaches found in the prior art rely on low thermal stability MTJs; such approaches are predicated on the theory that thermal fluctuations will drive a MTJ to randomly flip between its two stable states. In practice, this approach faces several technical challenges: it is extremely temperature sensitive, and will either not work on a large temperature range, or would require complex temperature compensation circuitry; relying on thermal fluctuations is slow, resulting in a blocking period before additional entropy can be harvested; and devices with low thermal stability tend to have poor magnetic properties (low magnetic resistance, broad distributions, et cetera), resulting in poor device performance. As such, it may be advantageous to, among other things, implement a purely on-chip system that generates truly random numbers from a high-entropy source with a minimal blocking period and which relies solely on electronic signals such that no additional circuits or power is required to process analogue signals (e.g., thermal fluctuations) into digital signals, and no off-chip components are required whose communications with the chip may be intercepted.

Magnetic tunnel junctions, as referred to herein, comprise at least two layers of magnetic metals, such as cobalt-iron, referred to as the free layer and the reference layer. The free layer and the reference layer are separated by an ultrathin layer of insulator, conventionally aluminum or magnesium oxide with a thickness of, for example, about 1 nm. The insulating layer may be so thin that electrons can tunnel through the barrier if a bias voltage is applied between the two metal electrodes. Magnetoresistive random-access memory (MRAM) devices are computer memory devices containing magnetic tunnel junctions that are designed to exploit this quantum mechanical effect of electron tunneling; the tunnel magnetoresistance (TMR) of the MRAM cell can be switched between a first state of low resistance where the two ferromagnetic layers have parallel magnetic dipole moments, and a second state of high resistance, where the two ferromagnetic layers have antiparallel magnetic dipole moments, by passing a write current through the MRAM cell stack. The write current to switch the MRAM cell from the first state to the second state differs in phase from the write current necessary to switch the MRAM cell from the second state to the first, and the two write currents run in opposing directions through the MRAM cells and their associated access transistors. The absolute and relative magnitudes of the two resistances and two write currents depend upon the configuration of the cell stack; for a standard connected MRAM cell stack comprising a bottom electrode, reference layer, tunnel barrier layer, free layer, and upper electrode, the anti-parallel to parallel write current is greater than the parallel to anti-parallel write current, as the parallel state has a high source degenerating resistance. For a MRAM cell stack with the layers reversed, the parallel to anti-parallel write current would be greater, as the anti-parallel state has a high source degenerating resistance.

For a standard connected MRAM cell stack, the TMR may be calculated as the anti-parallel state resistance minus the parallel state resistance, divided by the parallel state resistance plus any circuit parasitic series resistances. Parasitic series resistances arise from the circuit elements disposed between the MRAM cell stack and the its associated access transistor. The resistance increases with the distance between the MRAM cell stack and the transistor due to increasing amount of material through which the write currents must pass. The greater the TMR, the greater the difference between the two read currents and the higher the degree of sensing performance for the MRAM cell.

The magnetic tunnel junction can be made to oscillate utilizing, for example, spin transfer torque (STT). STT entails passing a current through a sufficiently thick ferromagnetic layer (often called the “fixed layer”) to produce a spin-polarized current, also known as the programming pulse; the spin-polarized current is then passed into the second, thinner magnetic layer (the “free layer”), transferring the angular momentum of the spin-polarized current into the free layer, changing its orientation. If the spin-polarized current is of sufficient magnitude to overcome the energy barrier of the free layer, the free layer will begin to oscillate between its parallel and anti-parallel states. The MTJ may also be made to oscillate utilizing, for example, the windmill effect, whereby in a stack comprising a free layer and a reference layer comprising a perpendicular polarizer, an applied current first destabilizes the free layer 404 as a result of its lower energy barrier relative to the reference layer 402 causing the free layer 404 to switch, and then the reference layer 402 to destabilize and switch; the reference layer 402 and free layer 404 may then switch alternately, resulting in an oscillation.

The MTJ has only two stable states, the parallel-antiparallel and antiparallel-parallel states. After the programming pulse has been applied to the MTJ, it will oscillate between these two states; to put the free layer magnetization into oscillation mode, the MTJ structure and bias conditions must be chosen so that the MTJ oscillates between its low and high resistance states with a frequency greater than 1 GHz. Once the programming pulse has been shut off, the MTJ will relax towards one of the two stable states; there is an equal probability that the MTJ will relax to the low resistance or high resistance states. In some embodiments of the invention, data is read from the MRAM cell by applying a known voltage to the MRAM cell and measuring the current through the cell to determine the resistance; a low resistance value may be read as a zero, and a high resistance value may be read as a one.

According to at least one embodiment, the invention is a method and system for generating truly random numbers using a MTJ-based oscillator electrically coupled to read and write circuitry by applying a programming pulse to the MTJ-based oscillators to excite the MTJ-based oscillator to oscillate between high-resistance and low-resistance states, shutting off the programming pulse and allowing the MTJ-based oscillator to relax towards one of the two stable resistance states with roughly equal probability, and reading the resistance state of the MTJ to produce a randomized value.

In some embodiments of the invention, the system may comprise an array of MTJ-based oscillators electrically coupled to read and write circuitry. The array may be sized based on the number of random values needed from the system; larger arrays produce a larger number of random values. In some embodiments of the invention, the MTJ-based oscillators may be fabricated directly onto a digital chip and may comprise no off-chip components. Off-chip components may comprise components such as analog-to-digital signal converters which may be fabricated separately from the digital chip, for instance with legacy technology nodes, and mounted next to the digital chips (such as microprocessors) at packing levels.

In some embodiments of the invention, the structure and bias conditions of the MTJ-based oscillators may be selected to enable the MTJ-based oscillators to oscillate between the high resistance and low resistance states with a frequency on the order of one to several GHz. The system may apply a programming pulse to the MTJ-based oscillator via the write circuit to drive the MTJ in its oscillating regime; the programming pulse may be significantly longer than the precession period of the MTJ such that the state of the MTJ after the write pulse is random, due to the phase noise. In other words, the duration of the programming pulse may be longer than the coherence time of the oscillations, and may be within the range of, for example, between five to a hundred nanoseconds. The pulse needs to be long enough to ensure the magnetization leaves the deterministic regime enters the precession regime; once the magnetization of the free layer oscillates, the free layer's state is random at any given time. The precession period may be the amount of time it takes for the MTJ to do one full rotation. After initiating oscillation via the programming pulse, the system may allow the magnetization to relax stochastically and return to a position of equilibrium. Once the magnetization has returned to equilibrium, the system may determine the resistance state of the MTJ using the read circuit. In some embodiments of the invention, the output of the RNG is independent of the write pulse duration as long as the write pulse duration is longer than the precession period of the MTJ.

In some embodiments of the invention, the MTJ-based oscillator may be a spin torque oscillator comprising three ferromagnetic layers: a reference layer, an in-plane free layer and a perpendicular polarizer. Each free layer and reference layer may include a magnetic material. The free and reference layers may be separated and magnetically de-coupled by a tunnel barrier layer. The free layer has a variable magnetization direction, and the reference layer has an invariable magnetization direction. A wide variety of layers and elements (e.g., an MTJ cap, multiple free/reference layers, etc.) may be included in an MTJ stack; the free layer may comprise cobalt-iron-boron (CoFeB) or any other suitable materials, the fixed layer may comprise nickel-iron alloy (NiFe), cobalt/nickel-iron/cobalt (Co/NiFe/Co) multilayers, or any other suitable materials, and the tunnel barrier layer may comprise aluminum oxide (AlO), aluminum titanium oxide (AlTiO), or magnesium oxide (MgO). Each layer may comprise a single layer or multiple laminated layers. The MTJ stack may further comprise other layers such as antiferromagnetic (AFM) layer; the AFM layer may comprise iridium manganese (Ir—Mn), manganese-platinum (Pt—Mn), platinum-palladium-manganese (Pt—Pd—Mn), nickel-manganese (Ni—Mn), or any other suitable materials. A perpendicular polarizer layer may be a ferromagnetic layer comprising CoFe or MgO and which has magnetic vectors perpendicular to the plane. The spin-torque oscillator induces oscillations by running a current through the polarizer to produce a spin-polarized current; this spin-polarized current is then directed into the free layer, transferring the angular momentum of the spin-polarized current to the free layer, and causing the free layer to oscillate.

In some embodiments of the invention, the MTJ-based oscillator may be an MTJ stack similar to a regular MRAM stack utilizing a simple perpendicular MTJ comprising two layers, a reference layer and a free layer, where the free layer has a lower energy barrier than the reference layer. This oscillator utilizes the windmill effect to oscillate, whereby an applied current first destabilizes the free layer as a result of its lower energy barrier relative to the reference layer causing the free layer to switch, and then the reference layer to destabilize and switch; the reference layer and free layer may then switch alternately, resulting in an oscillation. One advantage of the simple MTJ stack utilizing the windmill effect is that its structure is the same as a memory cell, such that the simple MTJ stack may be used as memory when not being utilized to create random numbers.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The following described exemplary embodiments provide a system, method, and program product to utilize magnetic tunnel junctions (MTJs) to generate true random numbers based on the MTJs relaxing with equal probability into one of two stable resistance states after being excited to oscillation by a programming pulse.

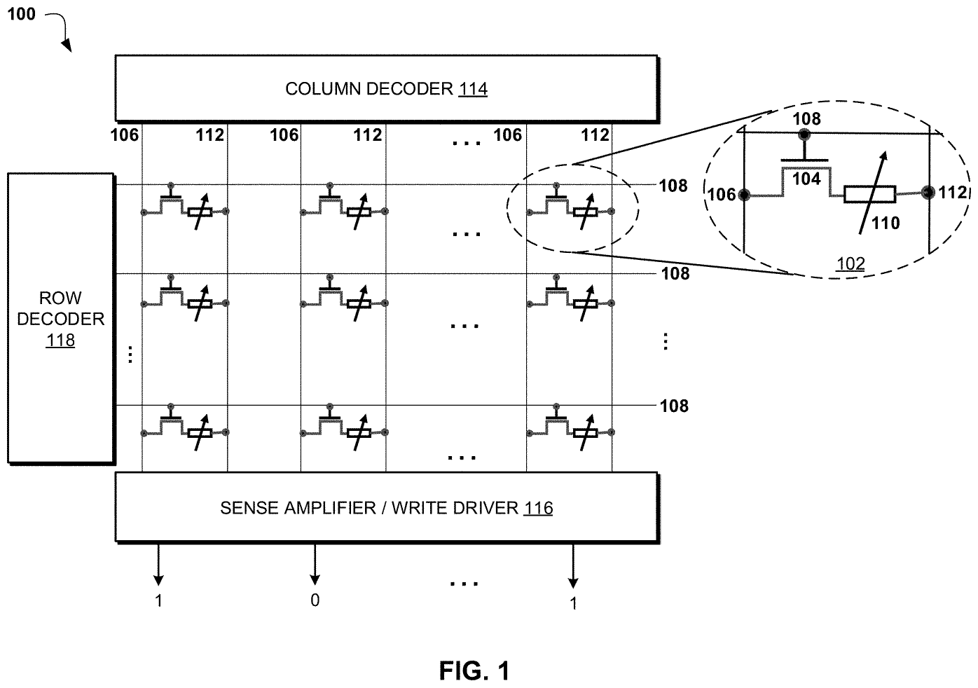

Referring to FIG. 1, a diagram illustrating an exemplary random number generator device 100 is depicted according to at least one embodiment of the present invention. Here, the random number generator device 100 comprises an array of magnetic-tunnel-junction (MTJ)-based oscillators 102 organized like a memory array, each MTJ-based oscillator 102 comprising a field effect transistor 104 which is connected to a source line 106 and a word line 108, as well as to magnetic tunnel junction 110. The magnetic tunnel junction 110 is in turn connected to a bitline 112. The MTJ-based oscillators 102 are electrically interconnected by the source lines 106, word lines 108, and bit lines 112. The source lines 106 and bit lines 112 are connected at one end to a column decoder 114, and the sense amplifier/write driver 116. The sense amplifier/write driver 116 reads the resistance states of the MTJ-based oscillators 102 by applying a read pulse to the MTJ-based oscillators 102. The word lines 108 are connected at one end to a row decoder 118.

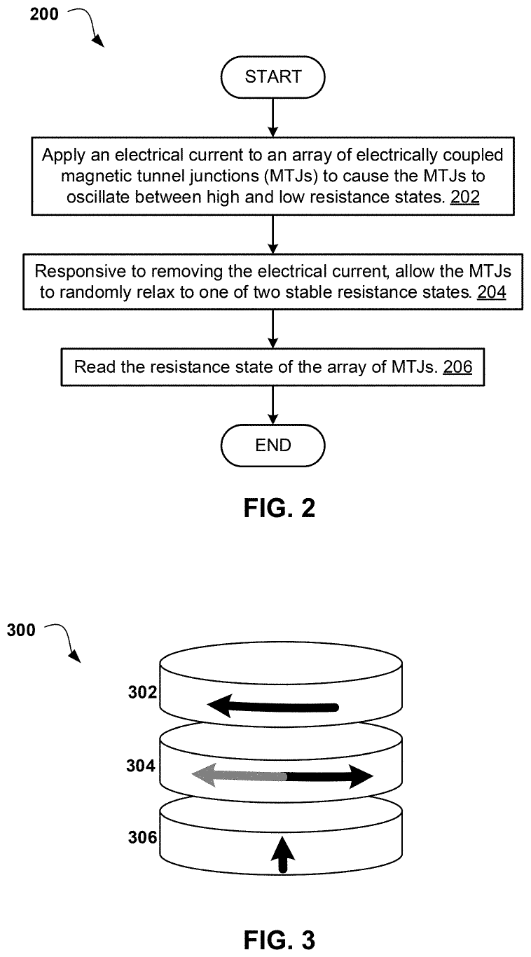

Referring now to FIG. 2, an operational flowchart illustrating a random number generation process 200 is depicted according to at least one embodiment. At 202, the system applies an electrical current to an array 100 of electrically coupled magnetic tunnel junctions (MTJs) 110 to cause the MTJs 110 to oscillate between high and low resistance states. The system may apply an electrical current in the form of a programming pulse to the MTJ-based oscillator 102 via the write circuit to drive the MTJ 110 in its oscillating regime; the programming pulse may be significantly longer than the precession period of the MTJ 110 such that the state of the MTJ 110 after the write pulse is random, due to the phase noise. In other words, the duration of the programming pulse may be longer than the coherence time of the oscillations, and may be within the range of, for example, between a three to a hundred nanoseconds. In some embodiments of the invention, the structure and bias conditions of the MTJ-based oscillators may be selected to enable the MTJ-based oscillators to oscillate between the high resistance and low resistance states with a frequency on the order of one to several GHz.

At 204, the system, responsive to removing the electrical current, allows the MTJs 102 to randomly relax to one of two stable resistance states. Once the system has removed the electrical current of the programming pulse, the system may wait for the amount of time necessary to allow the MTJs 102 to relax to one of the two stable resistance states, for example between 10 to 100 nanoseconds.

At 206, the system reads the resistance states of the array of MTJs. In some embodiments of the invention, the system reads data from the MTJ by passing a small read current with a known voltage, small enough in amplitude that no magnetization switching occurs, through the MTJ to measure the resistance of the MTJ; a low resistance value may be read as a zero, and a high resistance value may be read as a one.

Referring now to FIG. 3, a diagram of the structure of an exemplary magnetic-tunnel-junction (MTJ)-based oscillator 300 is depicted according to at least one embodiment of the present invention. The MTJ-based oscillator 300 may comprise three ferromagnetic layers, including a reference layer 302, an in-plane free layer 304, and a perpendicular polarizer 306. The spin-torque oscillator 300 induces oscillations by running a current through the polarizer 306 to produce a spin-polarized current; this spin-polarized current is then directed into the free layer 304, transferring the angular momentum of the spin-polarized current to the free layer 304, and causing the free layer 304 to oscillate.

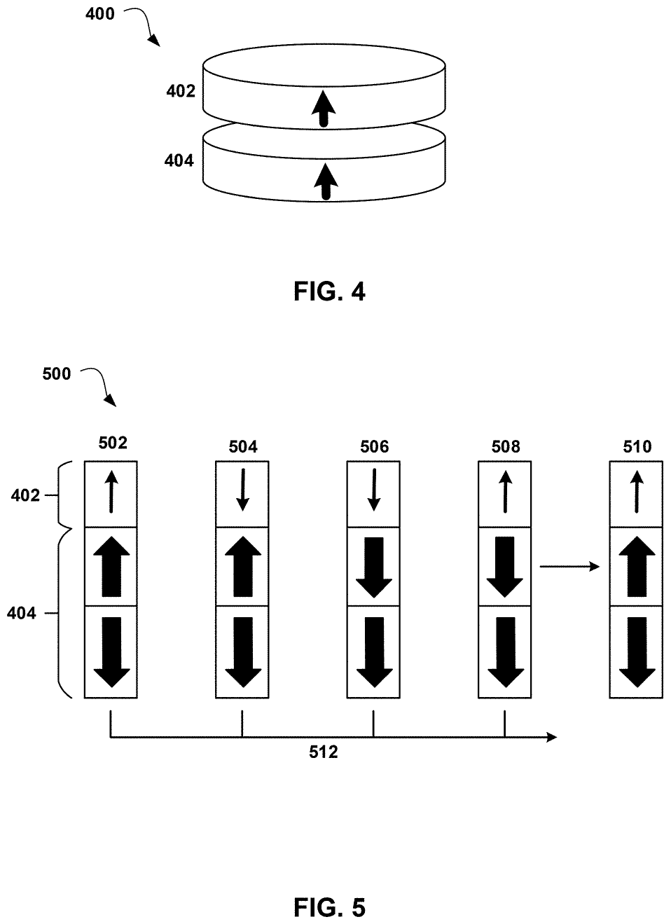

Referring now to FIG. 4, a diagram of the structure of an exemplary magnetic-tunnel-junction (MTJ)-based oscillator 400 is depicted according to at least one embodiment of the present invention. The MTJ-based oscillator 400 may be an MTJ stack similar to a regular MRAM stack utilizing a simple perpendicular MTJ comprising two layers, a reference layer 402 and a free layer 404, where the free layer 402 has a lower energy barrier than the reference layer 404. This oscillator 400 utilizes the windmill effect to oscillate, whereby an applied current first destabilizes the free layer 404 as a result of its lower energy barrier relative to the reference layer 402 causing the free layer 404 to switch, and then the reference layer 402 to destabilize and switch; the reference layer 402 and free layer 404 may then switch alternately, resulting in an oscillation. One advantage of the simple MTJ stack utilizing the windmill effect is that its structure is the same as a memory cell, such that the simple MTJ stack may be used as memory when not being utilized to create random numbers.

Referring now to FIG. 5, an example of the oscillation sequence 500 of the exemplary magnetic-tunnel-junction-based oscillator 400 of FIG. 4 is depicted according to at least one embodiment of the present invention. Here, at 502, the programming pulse 512 is applied to the MTJ stack 400 comprising the free layer 402 and reference layer 404, which starts out in a state of low resistance; since the free layer 402 has a lower energy barrier relative to the reference layer 404, the free layer 402 switches; at 504, the polarity of the free layer 402 has switched, and the MTJ stack 400 has flipped to its high resistance state. At this point, the programming pulse 512 has overcome the comparatively higher energy barrier of the reference layer 404, causing it to switch; at 506, the reference layer 404 has switched, flipping the MTJ stack 400 to its low resistance state. At 508, the free layer 402 switches again, resulting in the MTJ stack 400 flipping to its high resistance state. Between 508 and 510, the programming pulse 512 is switched off, allowing the MTJ stack 400 to relax to a low resistance state.

It may be appreciated that FIGS. 1-5 provide only illustrations of individual implementations and do not imply any limitations with regard to how different embodiments may be implemented. Many modifications to the depicted environments may be made based on design and implementation requirements.

The descriptions of the various embodiments of the present invention have been presented for purposes of illustration but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A processor-implemented method for generating true random numbers, the method comprising:
applying an electrical current to an entirely on-chip magnetic tunnel junction (MTJ) to cause the MTJ to oscillate between a high resistance state and a low resistance state; and
responsive to removing the electrical current and allowing the MTJ to randomly relax into the high resistance state or the low resistance state, reading a random resistance state of the MTJ.

2. The method of claim 1, wherein the electrical current is applied for a longer duration than a precession period of the MTJ.

3. The method of claim 1, wherein a structure and a bias condition of the MTJ is selected to enable the MTJ to oscillate with a frequency of one gigahertz.

4. The method of claim 1, wherein the MTJ is a spin-torque oscillator comprising a reference layer, a free layer, and a perpendicular polarizer.

5. The method of claim 1, wherein the MTJ is a simple perpendicular stack comprising at least two layers, a reference layer and a free layer.

6. The method of claim 5, wherein the MTJ is enabled to function as a memory cell and a random number generator.

7. The method of claim 1, wherein the electrical current lasts for between three to a hundred nanoseconds.

8. A random number generator comprising:
a chip comprising one or more magnetic tunnel junctions (MTJs), a write circuitry, and a read circuitry, wherein:
the write circuitry is enabled to provide an electrical current to excite the one or more MTJs to oscillate between a high resistance state and a low resistance state; and
the read circuitry is enabled to determine a random resistance state of the one or more MTJs responsive to removing the electrical current allowing the MTJ to relax towards either the high resistance state or the low resistance state randomly.

9. The random number generator of claim 8, wherein the electrical current is applied for a longer duration than a precession period of the one or more MTJs.

10. The random number generator of claim 8, wherein a structure and a bias condition of the MTJ is selected to enable the one or more MTJs to oscillate with a frequency of one gigahertz.

11. The random number generator of claim 8, wherein at least one of the one or more MTJs comprises a spin-torque oscillator comprising a reference layer, a free layer, and a perpendicular polarizer.

12. The random number generator of claim 8, wherein at least one of the one or more MTJs comprises a simple perpendicular stack comprising at least two layers, a reference layer and a free layer.

13. The random number generator of claim 12, wherein at least one of the one or more MTJs is enabled to function as a memory cell and a random number generator.

14. The random number generator of claim 8, wherein the electrical current lasts for between three to a hundred nanoseconds.

15. A computer program product for generating true random numbers, the computer program product comprising:
one or more computer-readable tangible storage medium and program instructions stored on at least one of the one or more tangible storage medium, the program instructions executable by a processor to cause the processor to perform a method comprising:
applying an electrical current to an entirely on-chip MTJ to cause the MTJ to oscillate between a high resistance state and a low resistance state; and
responsive to removing the electrical current and allowing the MTJ to randomly relax into the high resistance state or the low resistance state, reading the resistance state of the MTJ.

16. The computer program product of claim 15, wherein the electrical current is applied for a longer duration than a precession period of the MTJ.

17. The computer program product of claim 15, wherein a structure and a bias condition of the MTJ is selected to enable the MTJ to oscillate with a frequency of one gigahertz.

18. The computer program product of claim 15, wherein the MTJ is a spin-torque oscillator comprising a reference layer, a free layer, and a perpendicular polarizer.

19. The computer program product of claim 15, wherein the MTJ is a simple perpendicular stack comprising at least two layers, a reference layer and a free layer.

20. The computer program product of claim 19, wherein the MTJ is enabled to function as a memory cell and a random number generator.
